(19) United States
(12) Patent Application Publication
(10) Pub. No.: US 2010/0188826 A1
(43) Pub. Date: Jul. 29, 2010

(54) Connector device

(76) Inventor: Shih-Kun Yeh, Luchu Hsiang (TW)

Correspondence Address: Jackson Intellectual Property Group PLLC, 106 Starvale Lane, Shipman, VA, 22971, US

(21) Appl. No.: 12/073,802

(22) Filed: Mar. 10, 2008

(51) Int. Cl. H05K 1/00

(52) U.S. Cl. 361/749

(57) ABSTRACT

The connector device of the invention comprises at least a flexible flat cables (FFC) and a flexible printed circuit (FPC), or a flexible flat cable (FFC) which is positionally interconnected with a co-axial cable by a fixed structure for use in various electronic product applications, such as that it can be connected between display panel and signal control circuit in a notebook computer to improve the disadvantage of too high cost in conventional embodiment wherein only flexible printed circuit is used.

### BACKGROUND OF THE INVENTION

(a) Field of the Invention

The invention is related to a connector device, particularly to disclose a connector device which constitutes an electrical connection between different circuit components.

(b) Description of the Prior Art

Flexible printed circuit (FPC) is a flexible circuit board which can greatly reduced space required for circuit boards, therefore it is widely applied for various types of electronic products, particularly for portable electronic products which emphasize in convenience and volume minimization such as notebook computers, cell phones, digital cameras, portable VCD/DVD and vehicle display devices, etc. In practical applications, flexible printed circuit (FPC) is usually used as a connector for connection between different circuit components, such as between display panel and signal control circuit thereby to transmit image signals to display panel and control screen display on said display panel.

Referring to FIG. 1 which is a schematic view of the invention showing a conventional flexible printed circuit (FPC) connection design for notebook computers, wherein said notebook computer 1 has a LCD panel 11 with a central display area 12 installed with a peripheral circuit zone 13 at the peripheral area thereof, and said peripheral circuit zone 13 is installed with a plurality of driving circuits 14 thereon, while said driving circuit 14 is through flexible printed circuit 2 to connect with the keyboard or an input device 3, the control signal input from keyboard or input device 3 is transmitted through flexible printed circuit 2 to driving circuit 14 via display area 12 to display corresponding images, wherein flexible printed circuit 2 of soft material properties in connection with keyboard or input device 3 can designed to different shapes of routes so as to match with the appearances of other circuit components (such as circuit board). Nonetheless, said flexible printed circuit has a higher cost, therefore is less conforming to economic effectiveness.

### SUMMARY OF THE INVENTION

The connector device of the invention comprises at least a flexible flat cables (FFC) and a flexible printed circuit (FPC), or a flexible flat cable (FFC) which is positionally interconnected with a co-axial cable by a fixed structure for use in various electronic product applications, such as that it can be connected between display panel and signal control circuit in a notebook computer to improve the disadvantage of too high cost in conventional embodiment wherein only flexible printed circuit is used.

### BRIEF DESCRIPTION OF THE DRAWINGS

FIG. 1 is a schematic view of the invention showing a conventional flexible printed circuit (FPC) connection design for notebook computers.

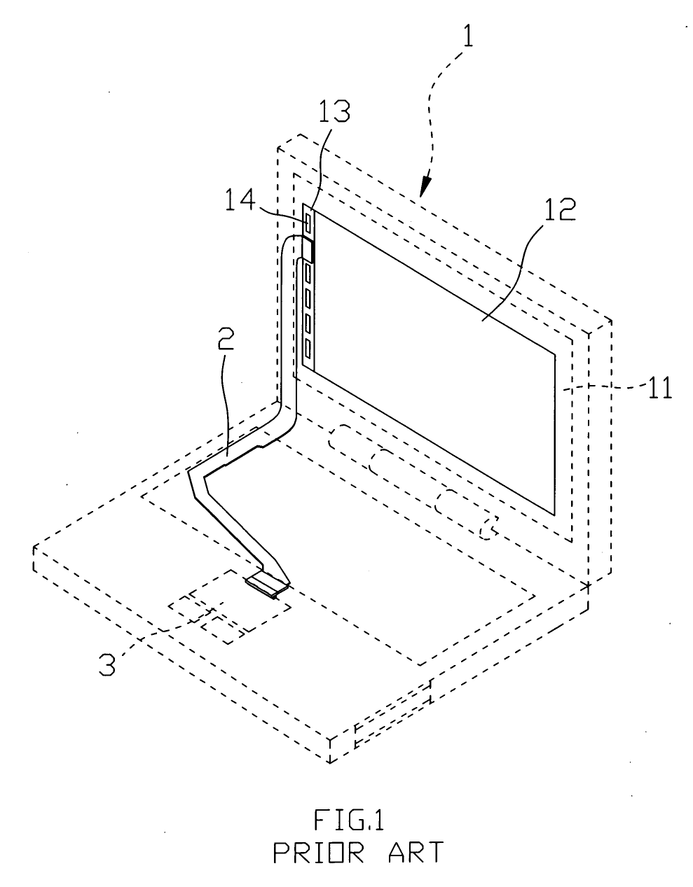

FIG. 2 is a schematic view showing the first embodiment of connector device for a connection design application in notebook computers

FIG. 3 is a cross-sectional structural schematic view of flexible flat cable of the invention.

FIG. 4 is a structural schematic view showing the fixing device in the first embodiment of the invention.

FIG. 5 is another structural schematic view showing the fixing device in the first embodiment of the invention.

FIG. 6 is a schematic view showing the second embodiment of connector device for a connection design application in notebook computers

FIG. 7 is a structural schematic view showing the fixing device in the second embodiment of the invention.

FIG. 8 is another structural schematic view showing the fixing device in the second embodiment of the invention.

FIG. 9 is a further structural schematic view showing the fixing device in the second embodiment of the invention.

### DETAIL DESCRIPTION OF THE PREFERRED EMBODIMENTS

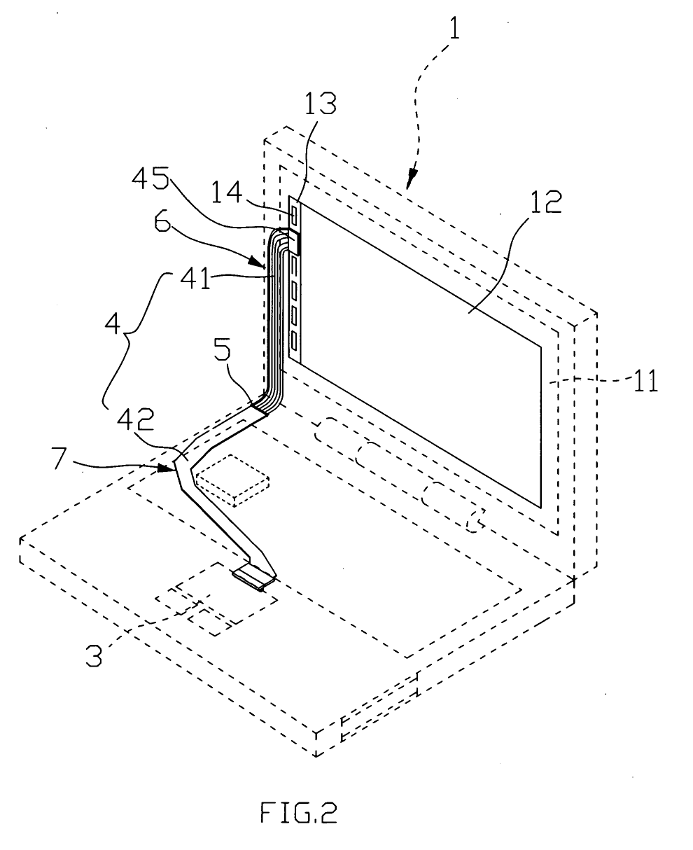

The connector device 4 of the invention as shown in FIG. 2 at least comprises a flexible flat cable

(FFC) 41, a flexible printed circuit (FPC) 42 and a fixing device 5, wherein said connector device can be applied in portable electronic products including notebook computers, cell phones, digital cameras, portable VCD/DVD and vehicle display units, etc. Said connector device 4 as shown by the embodiment of FIG. 2 is applied in notebook computer 1, wherein said notebook computer 1 has a LCD panel 11 with a central display area 12 installed with a peripheral circuit zone 13 at the peripheral area thereof, and said peripheral circuit zone 13 is installed with a plurality of driving circuits 14 thereon, while said flexible flat cable 41 is installed with a connector 45 at one end thereof, whereby said driving circuit 14 is through connector 45 and flexible flat cable 41 to further connect with flexible printed circuit 42 on a fixing device 5, while as flexible printed circuit 42 is connected with the keyboard or an input device 3, the control signal input from keyboard or input device 3 is transmitted through connector device 4 to driving circuit 14 via display area 12 to display corresponding images, whereas flexible printed circuit 42 is connected with keyboard or input device 3, wherein the soft material properties of flexible printed circuit 42 can be designed to different shapes of routes so as to match with the appearances of other circuit components (such as circuit board).

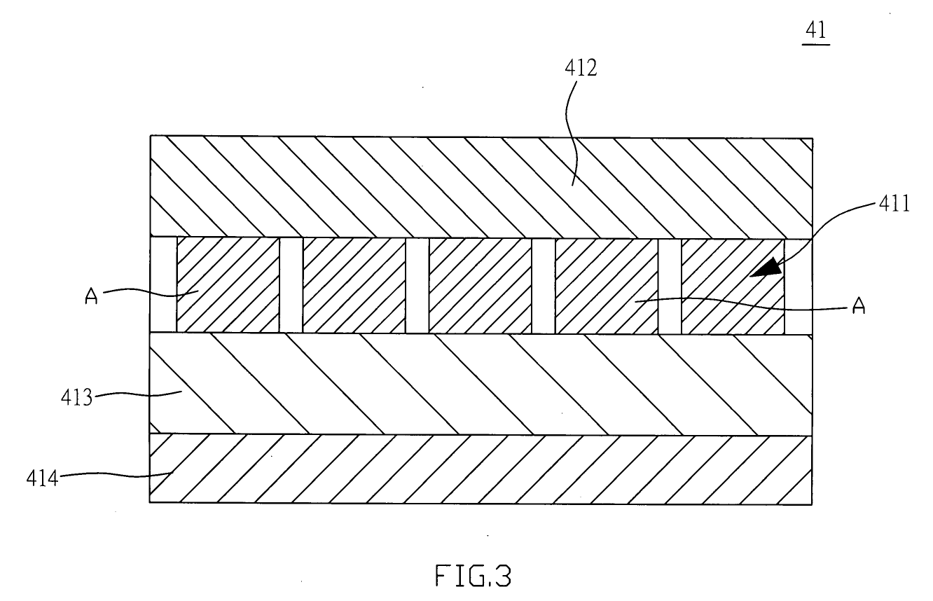

Said flexible flat cable 41 thereof as shown in FIG. 3 includes:

A conductive layer 411 comprises a plurality of copper wires A in parallel arrangements, wherein total thickness of said conductive layer 411 is 0.018˜0.1 mm, and width is 0.2˜0.8 mm.

A first insulation layer 412 is installed to one side of said conductive layer 411, wherein said first insulation layer 412 is made of poly-ethylene-terephthalate (PET) with a thickness of 0.04˜0.3 mm.

A second insulation layer 413 is installed to another side of said conductive layer 411 relative to the side of said first insulation layer 412, wherein said second insulation layer 413 is made of poly-ethylene-terephthalate (PET) or polyimide with a thickness of 0.04˜0.3 mm.

A grounding board 414 is installed to second insulation layer 413 relative to another side of said conductive layer 411, wherein said grounding board 414 can be a copper or aluminum board.

Said conductive layer 411 being enclosed by first and second insulation layers 412, 413 to constitute an integral body has characteristics of softness, anti-burning, anti-heat and anti-coolness can be simply made in lower cost, wherein said flexible flat cable 41 has a characteristic impedance (Z0) which is relative to width and thickness of conductive layer 411 thereof in reverse ratio relationship.

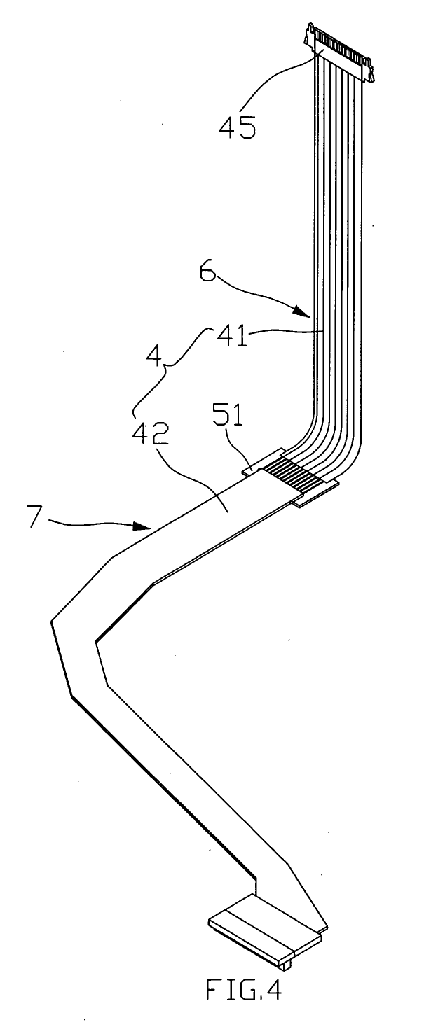

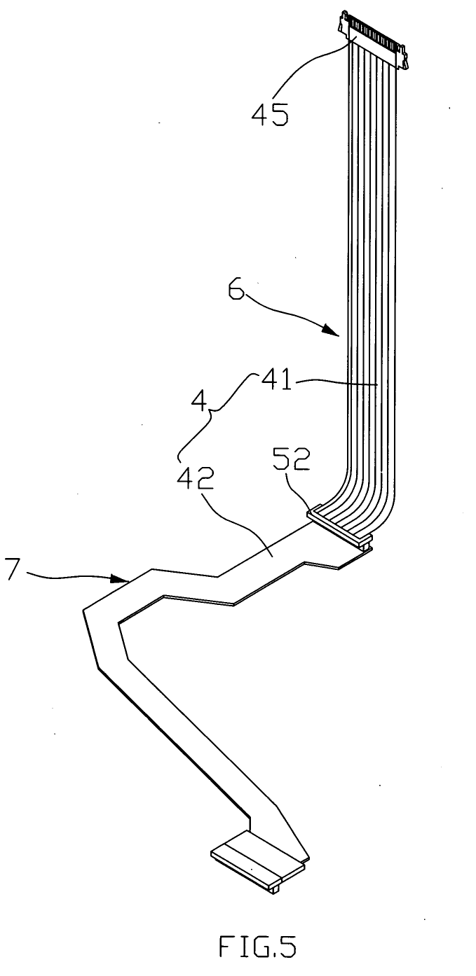

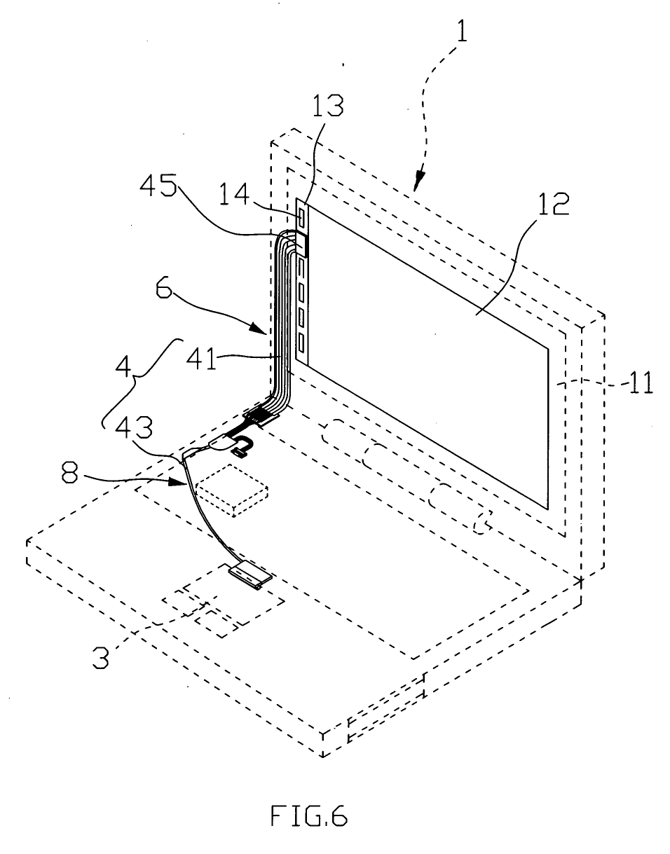

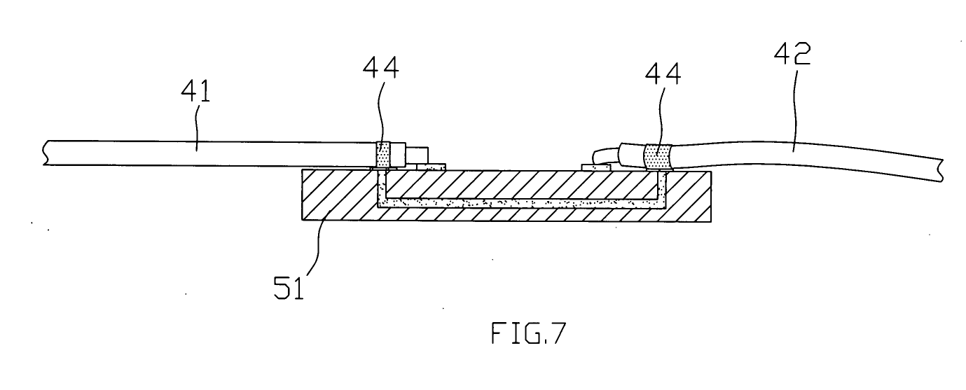

In practical embodiments, the fixing device 5 between said flexible flat cable 41 and flexible printed circuit 42 can be formed by welding as shown in FIG. 2; or as shown in FIG. 4, said flexible flat cable 41 and flexible printed circuit 42 can be respectively affixed to two sides of a circuit board 51 which is then constitute a positionally connection between said flexible flat cable 41 and flexible printed circuit 42, or as shown in FIG. 5, said flexible flat cable 41 and flexible printed circuit can be positionally inter-connected through a connector 52. Further, as delineated by another embodiment shown in FIG. 6, said connector device 4 can also comprise a flexible flat cable (FFC) 41 and a co-axial cable 43, wherein driving circuit 14 is trough connector 45, flexible flat cable 41 to connect with co-axial cable 43 via fixing device 5 in the notebook computer, while co-axial cable 43 is connected to keyboard or input device 3, thereby the control signal input from keyboard or input device 3 is transmitted through connector device 4 to driving circuit 14 via display area 12 to display corresponding image; and further in the embodiment shown in FIG. 7, said fixing structure can be a circuit board 51 to positionally connect flexible printed circuit 41 and co-axial cable 43, wherein said fixing structure unquestionably can be formed by welding or can be positionally inter-connect with co-axial axial through a connector to achieve the same positional connection effect.

It is worth to mention that the invention utilizing a fixing device to constitute the positional inter-connection between flexible flat cable (FFC) and flexible printed circuit (FPC) as well as between flexible printed circuit (FFC) and co-axial cable can be installed for connection between display panel and signal control circuit in a notebook computer to improve the disadvantage of too high cost in conventional embodiment wherein only flexible printed circuit is used, wherein the flexibility of flexible printed circuit and co-axial cable can be utilized to be designed or bended according to installed circuit board to different shapes of routes so as to match with the appearances of other circuit components (such as circuit board).

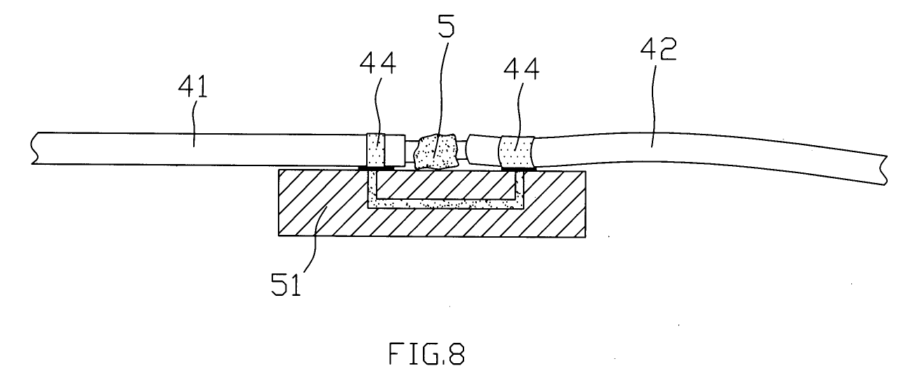

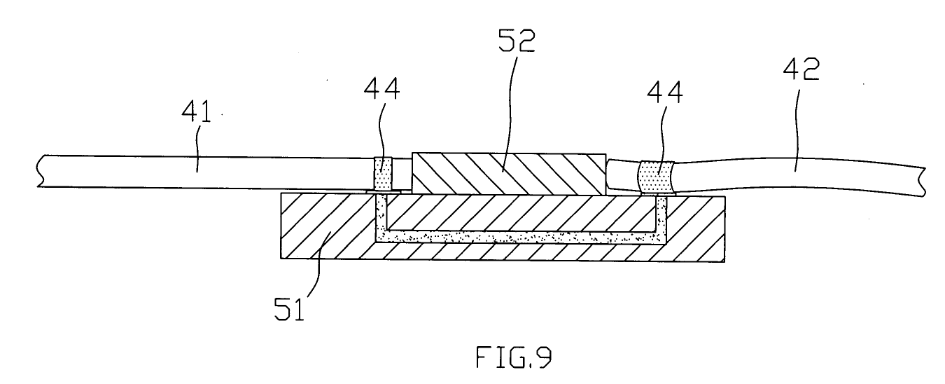

Furthermore, said connector device can be by utilizing the fixing structure to produce EMI prevention characteristics to avoid conditions of function disarrays, transmission errors and poor communications causing by magnetic field or electromagnetic wave. FIG. 7 is a structural schematic view showing that flexible flat cable 41 is connected with co-axial cable 43 through a circuit board 51, wherein the conducting materials 44 (can be made by wrapping exteriors of flexible flat cable and co-axial cable by conducting tapes) can be respectively installed to circuit board 51 near where to connect with flexible flat cable 41 and to connect with co-axial cable 43, whereby said conducting material 44 is connected with circuit board 51 to conduct magnetic field and electromagnetic wave for EMI prevention. Naturally, if said fixing structure is connected by welding or by a connector, the welding joint or connector 52 is affixed with a circuit board 51 at one side thereof, similarly as shown in FIGS. 8 and 9, conducting materials 44 are respectively installed to circuit board 51 near where to connect with flexible flat cable 41 and to connect with co-axial cable 43, whereby said conducting material is connected with circuit board 51 to conduct magnetic field and electromagnetic wave for EMI prevention.

As described above, the invention has disclosed a better connector device, therefore the new type patent is applied herein according to law, wherein aforesaid embodiments and accompanied Figs. are preferred embodiments of the invention which are not intended to limit the scope of the invention. Therefore, all same or similar to structures, devices or characteristics of the invention shall be belong to purposes and claims of the invention.

I claim:

1. A connector device at least comprises:
A flexible printed circuit (FPC);
A said flexible flat cable (FFC) is installed with a connector at one end thereof, and is inter-connected with a flexible printed circuit at the other end, wherein said flexible flat cable has a conductive layer, first and second insulation layers and a grounding board; said conductive layer has a thickness of 0.018˜0.1 mm and a width of 0.2˜0.8 mm; said first insulation layer is installed to one side of said conductive layer with a thickness of 0.04˜0.3 mm; said second insulation layer is installed to another side of said conductive layer relative to the side of said first insulation layer with a thickness of 0.04˜0.3 mm, and said grounding board is installed to second insulation layer relative to another side of said conductive layer; and
A fixing structure is installed between flexible printed circuit (FPC) and flexible flat cable (FFC) to positionally inter-connect said flexible printed circuit (FPC) and flexible flat cable (FFC).

2. The connector device of claim 1, wherein said fixing structure can be welded.

3. The connector device of claim 2, wherein said welding joint whereof is affixed with a circuit board, and conducting materials can be respectively installed to circuit board near where to connect with flexible flat cable and to connect with co-axial cable, whereby said conducting material is connected with said circuit board.

4. The connector device of claim 1, wherein said fixing structure can be a circuit board.

5. The connector device of claim 4, wherein conducting materials can be respectively installed to circuit board near where to connect with flexible flat cable and to connect with flexible printed circuit, whereby said conducting material is connected with said circuit board.

6. The connector device of claim 1, wherein said fixing structure can be a connector.

7. The connector device of claim 6, wherein said connector is affixed with a circuit board at one side thereof, and conducting materials can be respectively installed to circuit board near where to connect with flexible flat cable and to connect with flexible printed circuit, whereby said conducting material is connected with said circuit board.

8. The connector device of claim 1, wherein said first and second insulation layers are made of poly-ethylene-terephthalate (PET) or polyimide.

9. The connector device of claim 1, wherein said conductive layer includes a plurality of copper wires in parallel arrangement.

10. The connector device of claim 1, wherein said grounding board can be a copper or aluminum board.

11. A connector device at least comprises:
A co-axial cable:
A said flexible flat cable (FFC) is installed with a connector at one end thereof, and is inter-connected with a co-axial cable at the other end, wherein said flexible flat cable has a conductive layer, first and second insulation layers and a grounding board; said conductive layer has a thickness of 0.018˜0.1 mm and a width of 0.2˜0.8 mm; said first insulation layer is installed to one side of said conductive layer with a thickness of 0.04˜0.3 mm; said second insulation layer is installed to another side of said conductive layer relative to the side of said first insulation layer with a thickness of 0.04˜0.3 mm, and said grounding board is installed to second insulation layer relative to another side of said conductive layer; and
A fixing structure is installed between co-axial cable and flexible flat cable (FFC) to positionally inter-connect said co-axial cable and flexible flat cable (FFC).

12. The connector device of claim 11, wherein said fixing structure can be welded.

13. The connector device of claim 12, wherein said welding joint whereof is affixed with a circuit board, and conducting materials can be respectively installed to circuit board near where to connect with flexible flat cable and to connect with co-axial cable, whereby said conducting material is connected with said circuit board.

14. The connector device of claim 11, wherein said fixing structure can be a circuit board.

15. The connector device of claim 14, wherein conducting materials can be respectively installed to circuit board near where to connect with flexible flat cable and to connect with co-axial cable, whereby said conducting material is connected with said circuit board.

16. The connector device of claim 11, wherein said fixing structure can be a connector.

17. The connector device of claim 16, wherein said connector is affixed with a circuit board at one side thereof, and conducting materials can be respectively installed to circuit board near where to connect with flexible flat cable and to connect with co-axial cable, whereby said conducting material is connected with said circuit board.

18. The connector device of claim 11, wherein said first and second insulation layers are made of poly-ethylene-terephthalate (PET) or polyimide

19. The connector device of claim 11, wherein said conductive layer includes a plurality of copper wires in parallel arrangement.

20. The connector device of claim 11, wherein said grounding board can be a copper or aluminum board
